(19) United States
(12) Patent Application Publication
(10) Pub. No.: US 2011/0156829 A1
(43) Pub. Date: Jun. 30, 2011

(54) OSCILLATOR COMBINED CIRCUIT, SEMICONDUCTOR DEVICE, AND CURRENT REUSE METHOD

(75) Inventor: Jianqin WANG, Kanagawa (JP)

(73) Assignee: RENESAS ELECTRONICS CORPORATION, Kanagawa (JP)

(21) Appl. No.: 12/979,156

(22) Filed: Dec. 27, 2010

(30) Foreign Application Priority Data
Dec. 28, 2009 (JP) 2009-297134

(51) Int. Cl. H03B 5/12

(52) U.S. Cl. 331/117 FE

(57) ABSTRACT

An oscillator combined circuit comprises: an oscillator including a resonance circuit that includes an inductor and capacitors, and a frequency divider that includes a differential pair that receives an oscillation output signal of the oscillator, and forms current paths from a power supply side, with first ends thereof on a side opposite to the first power supply being connected to the center tap of the inductor of the oscillator. The oscillator and the frequency divider are cascode-connected between ground and the power supply and a DC power supply current flowing from a DC supply current terminal of the frequency divider to a ground side is reused as a power supply current of the oscillator.

### REFERENCE TO RELATED APPLICATION

This application is based upon and claims the benefit of the priority of Japanese patent application No. 2009-297134, filed on Dec. 28, 2009, the disclosure of which is incorporated herein in its entirety by reference thereto.

### TECHNICAL FIELD

This invention relates to an oscillator, and in particular, relates to an oscillator combined circuit, a semiconductor device, and a current reuse method, that are preferable for lowering power consumption when applied to a frequency synthesizer or the like.

### BACKGROUND

In high frequency integrated circuits used in communication devices, mobile telephone units, and the like, it is necessary to generate a carrier signal by a local oscillator, and to lock frequency and phase of a carrier signal by using a phase locked loop (abbreviated as PLL).

FIG. 10 is a diagram schematically showing an example of a configuration of a typical high frequency integrated circuit that generates a local signal to be supplied to the mixer. As shown in FIG. 10, an output signal of a voltage controlled oscillator (abbreviated as VCO) 10, which varies an oscillation frequency according to a frequency control voltage, is supplied via a buffer amplifier 50 to a frequency divider 20 and a mixer 60. A signal supplied from the buffer amplifier 50 to the mixer 60 is a local signal. With regard to an output of the frequency divider 20, a phase difference from a reference signal is detected by a phase detector (abbreviated as PD), a capacitor is charged and discharged based on a phase detection result by a charge pump (abbreviated as CP), and an output voltage of the charge pump (CP) is smoothed by a loop filter (low pass filter LPF), to be supplied to the VCO 10 as the frequency control voltage. In the example shown in FIG. 10, the voltage controlled oscillator 10 includes an L and C parallel resonance circuit, and a VCO cross pair 120 (a transistor pair with sources connected to ground, and gates and drains cross-connected) connected between the L and C parallel resonance circuit and ground; a midpoint of an inductor 111 of the resonance circuit is connected to a power supply, and the frequency control voltage is supplied to a connection point of capacitors (varactor diode: variable capacitance element) 112a and 112b, connected in series between output of the resonance circuit. It is to be noted that in FIG. 10, PD, CP, and LPF, which are component elements of the PLL, are considered as one and have a reference symbol 40 (PLL element), and the VCO 10, the buffer amplifier 50, the frequency divider 20, and the PD, CP, and LPF 40 form the PLL.

In this configuration, respective DC supply currents are necessary to operate the voltage controlled oscillator 10, the frequency divider 20 and the mixer 60. Since these circuits operates in high frequency, relatively large power is consumed in the integrated circuit overall.

On the other hand, in a mobile communication device such as a mobile telephone unit or the like, in order to have a long standby time, lower power consumption in transmission and reception circuits is required.

As means of lowering power consumption, there exist various methods such as lowering an operation voltage or reducing a current in each functional block, and a technique of reusing a current of a functional block has been proposed. For example, Patent Document 1 (Patent Application Publication No. 2002-529949), as shown in FIG. 11, discloses a technique in which a mixer having a Gilbert cell structure (a Gilbert multiplier formed of transistor pairs (M7 and M8), (M3 and M4), and (M5 and M6)) is connected to an output stage of an oscillator in which a cross pair (M1 and M2) is connected to a parallel resonance circuit in which a capacitor C (variable capacitance) is connected in parallel to a series circuit of an inductor L and a resistor R), and a current is reused by sharing a current of the oscillator with the mixer. It is to be noted that FIG. 11 is cited from FIG. 5 of Patent Document 1. In FIG. 11, coupled sources of the cross pair transistors M1 and M2 are connected to a drain of an nMOS transistor 30 (current source) having s source connected to ground and forming an output of a current mirror. The nMOS transistor 30 has a gate connected to a gate and a drain of an nMOS transistor 32 forming an input of a current mirror. The drain of an nMOS transistor 32 is connected to a current source 34. Sources of the transistors 30 and 32 are connected in common to ground. In FIG. 11, a supply terminal of the oscillator is arranged so as to transmit a local oscillation signal current and a DC supply current, a mixer supply terminal is connected to the oscillator supply terminal and to receive a DC supply current and an AC current of the local oscillator, from the oscillator supply terminal.

In this type of a stack configuration, an oscillation signal of the oscillator is supplied to the mixer in the form of an AC current and a DC supply current is supplied and with regard to a DC supply current of the oscillator, the DC supply current of the mixer is shared when viewed from the overall circuit, as a result of which the mixer current is saved and low power consumption is realized.
[Patent Document 1] JP Patent Kohyo Publication No. JP-P2002-529949A

### SUMMARY

The entire disclosure of Patent Document 1 is incorporated herein by reference thereto. An analysis of related art is given as follows.

In the related art technology shown in FIG. 11, since a mixer (Gilbert multiplier) is directly connected to an oscillator, isolation between the mixer and the oscillator deteriorates. For example, when a strong disturbing signal (disturbing wave) is received by the mixer, the disturbing signal reaches a resonance circuit of the oscillator, pulling (frequency shifting of a VCO caused by the disturbing signal) or pushing (fluctuation caused in an oscillation frequency when the power supply voltage of the VCO fluctuates transiently) effects may be generated in the oscillator, and the operation of the oscillator may become unstable.

In accordance with one aspect of the present invention, there is provided an oscillator combined circuit comprising:

an oscillator including a resonance circuit that includes an inductor and a capacitors connected in parallel; and

a circuit including a differential pair that receives an oscillation output signal of the oscillator, and that forms first and second current paths from a first power supply, the first and second current paths having respective first ends on a side opposite to the first power supply coupled together and connected to the center tap of the inductor of the oscillator,

the oscillator and the circuit including the differential pair being cascode-connected between a second power supply and the first power supply.

In accordance with one aspect of the present invention, there is provided a method of reusing a current in a circuit comprising an oscillator having a resonance circuit including an inductor and a capacitor connected in parallel; and another circuit including a differential pair that receives an oscillation output signal of the oscillator and forms first and second current paths from a first power supply side, the method comprising:

connecting respective first ends of the first and second current paths on a side opposite to the first power supply in common to the center tap of the inductor of the oscillator;

cascode-connecting the oscillator and the another circuit between a second power supply and the first power supply; and

using, by the oscillator, a current supplied from the commonly connected first ends of the first and second current paths of the another circuit including the differential pair, as a power supply current of the oscillator.

According to the present invention, it is possible to share a DC power supply current by a circuit combined with an oscillator, to eliminate effect of a disturbing wave and avoid unstable operation of the oscillator, and to realize lower power consumption.

Still other features and advantages of the present invention will become readily apparent to those skilled in this art from the following detailed description in conjunction with the accompanying drawings wherein only exemplary embodiments of the invention are shown and described, simply by way of illustration of the best mode contemplated of carrying out this invention. As will be realized, the invention is capable of other and different embodiments, and its several details are capable of modifications in various obvious respects, all without departing from the invention. Accordingly, the drawing and description are to be regarded as illustrative in nature, and not as restrictive.

### BRIEF DESCRIPTIONS OF THE DRAWINGS

FIG. 1 is a diagram showing a configuration of an embodiment of the present invention.

FIG. 2 is a diagram showing a configuration of another embodiment of the present invention.

FIGS. 3A and 3B are diagrams showing configurations of cross pairs of FIG. 1 and FIG. 2.

FIGS. 4A to 4C are diagrams showing an example of a differential circuit.

FIG. 5 is a diagram showing a configuration of a first exemplary embodiment of the present invention.

FIG. 6 is a diagram showing a configuration of a second exemplary embodiment of the present invention.

FIG. 7 is a diagram showing a configuration of a third exemplary embodiment of the present invention.

FIG. 8 is a diagram showing a configuration of a fourth exemplary embodiment of the present invention.

FIG. 9 is a waveform diagram showing operation of an embodiment of the present invention.

FIG. 10 is a diagram schematically showing a typical configuration example of a local oscillation circuit.

FIG. 11 is a diagram showing a configuration of related technology (Patent Document 1).

### PREFERRED MODES

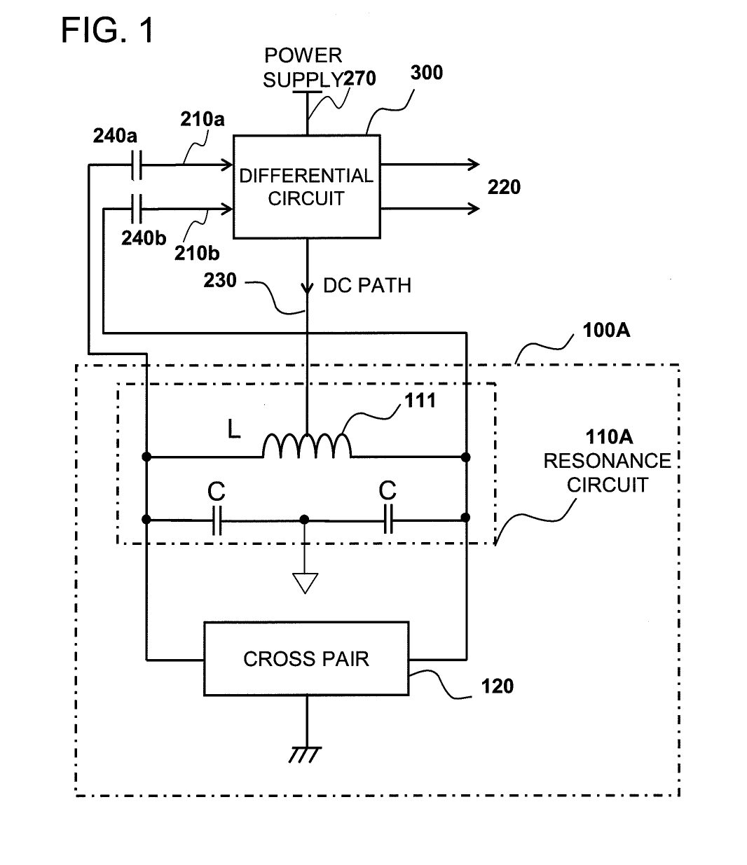

Preferred modes of the present invention will be described below. FIG. 1 is a diagram showing a configuration of one exemplary embodiment of the present invention. In FIG. 1, an example is shown that includes a differential circuit 300 as a circuit which shares a DC current from a power supply with an oscillator. A differential pair (transistor pair) of the differential circuit 300 forms first and second current paths from the power supply. The first and second current paths have ends on a side opposite to the power supply connected in common to a midpoint (center tap) of an inductor of the oscillator 100A to supply a DC supply current to the oscillator 100A.

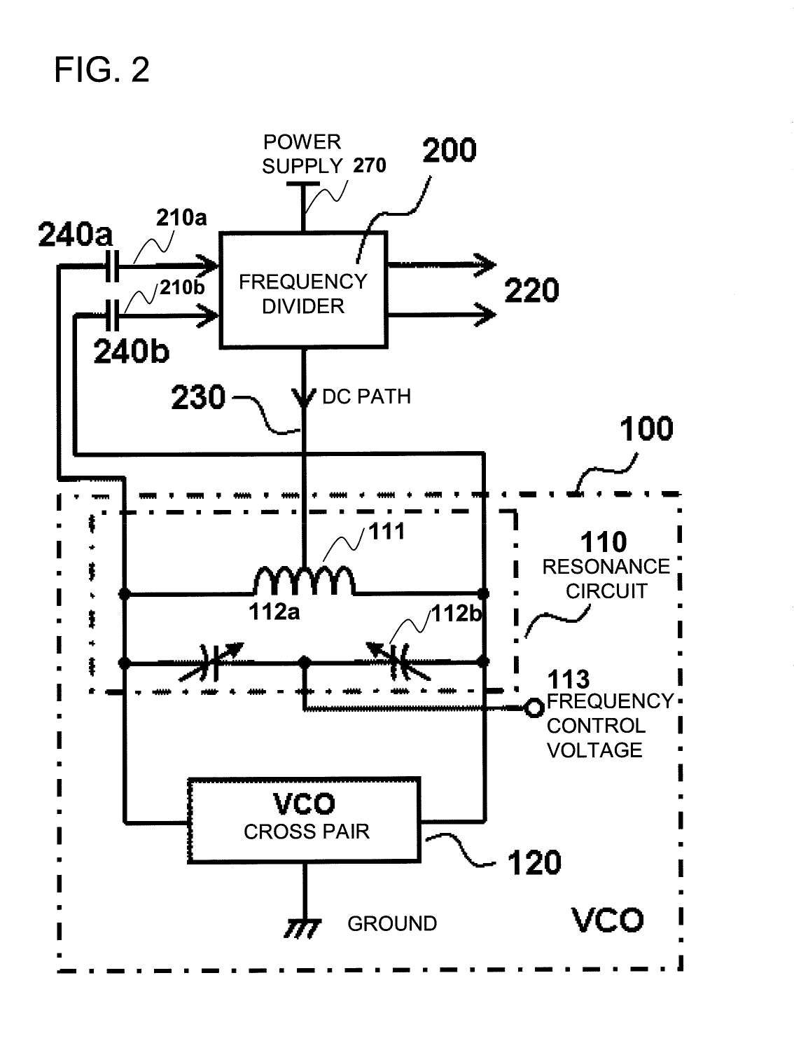

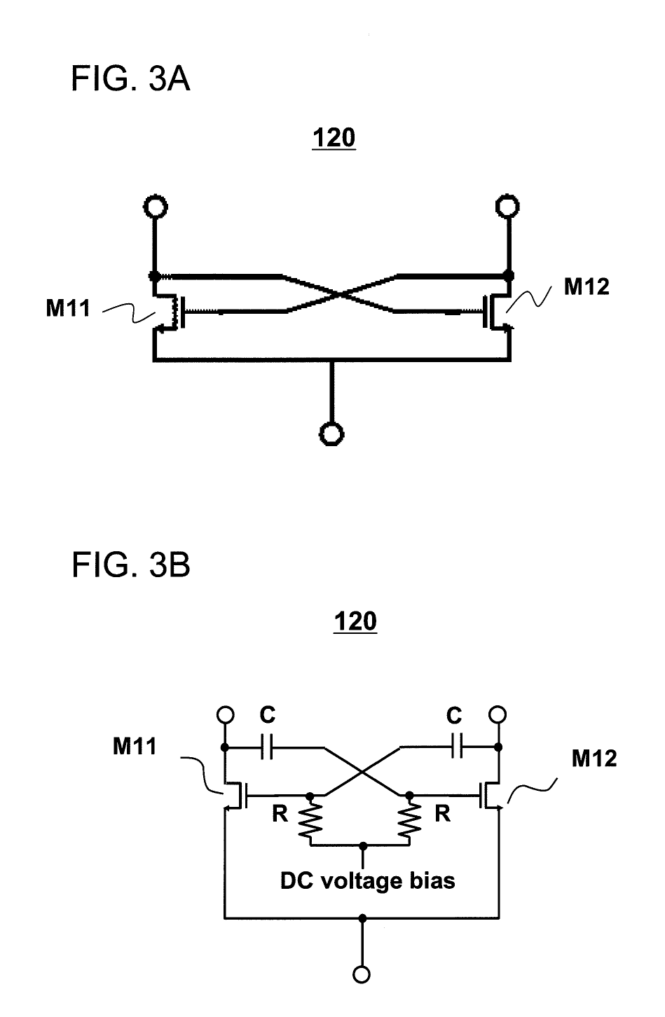

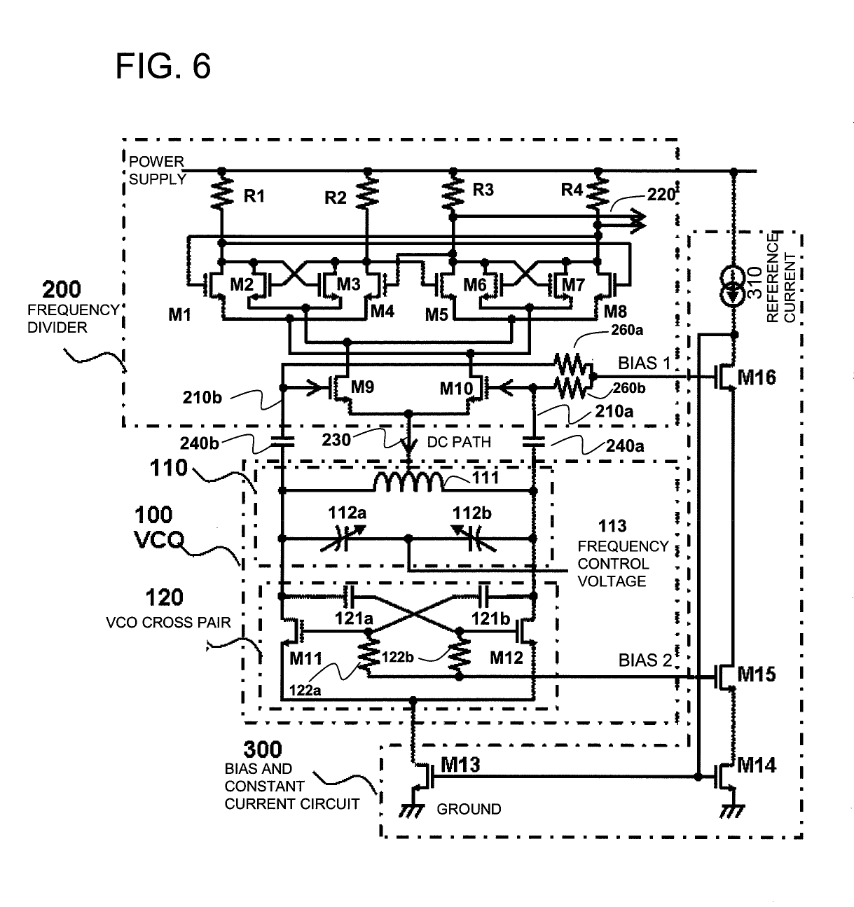

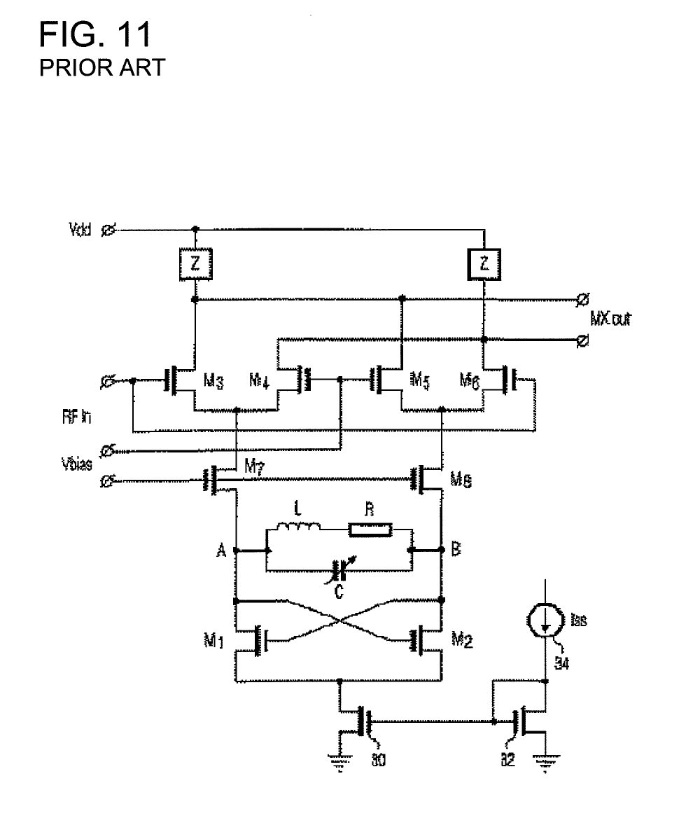

The oscillator 100A, which includes a resonance circuit 110A and a cross pair 120, has output ends that provide differential outputs of an oscillation signal, and that are connected to input ends (differential input terminals) 210 of the differential circuit 300. The resonance circuit 110A includes a parallel circuit of an inductor (L) 111 and a capacitor which includes two capacitors (C) connected in series between the both ends of the inductor (L) 111. The capacitors (C) may be variable-capacitance elements in which a capacitance value is able to vary. The cross pair 120, which is connected between outputs of the resonance circuit 110A and ground, as shown in FIG. 3A, includes nMOS transistors M11 and M12, having sources connected to ground, and gates mutually cross connected to respective drains of the transistors M12 and M11. The drains of the nMOS transistors M11 and M12 are respectively connected to the both ends of the inductor (L) 111. It is to be noted that the cross pair 120 is referred to as a transistor pair in which a gate of each one transistor of the transistor pair is cross connected to a drain of the other transistor and vice versa, and forms a configuration the same as a VCO cross pair 120 of FIG. 2, or M1 and M2 of FIG. 11. It is to be noted that the cross pair 120 is not limited to a configuration of FIG. 3A. and as shown in FIG. 3B for example, nMOS transistors M11 and M12 have sources connected to ground and have gates cross-connected via capacitors C to drains of the other transistors M2 and M1, respectively, and have each gate connected to a DC voltage bias terminal via a resistor R. It is to be noted that the configuration of FIG. 3B is used in an exemplary embodiment of FIG. 6 which will be described later.

Capacitors 240a and 240b connected between outputs of the oscillator 100A and the differential input terminals 210 are capacitors (coupling capacitors) for cutting off a DC current. The differential input terminals 210 of the differential circuit 300 are AC coupled via the coupling capacitors 240a and 240b to differential outputs of the oscillator 100A, and output a differential output signal from the differential output terminals 220. The differential circuit 300 has a power supply connection terminal 270 on one side (high potential side), and has a DC supply current terminal 230 on an opposite side (low potential side). The power supply terminal 270 is connected to a power supply. The DC supply current terminal 230 is connected to a center tap of the inductor 111 of the resonance circuit 110A, and a DC supply current is supplied to the nMOS transistors M11 and M12 of the cross pair 120 via the inductor 111.

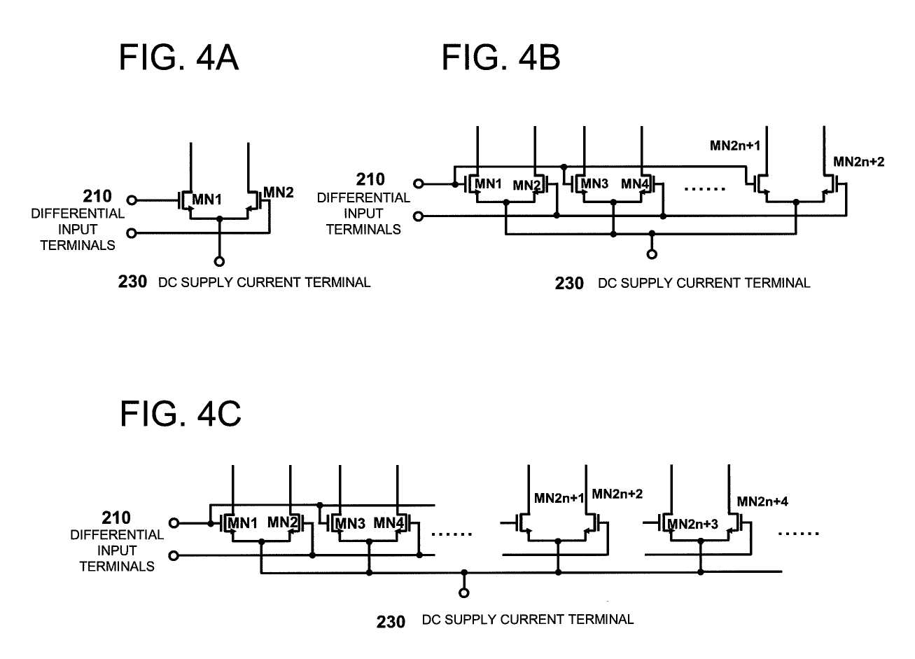

FIG. 4A is a diagram showing a configuration example of the differential circuit 300 of FIG. 1. The differential circuit 300 includes an nMOS transistor pair (differential pair) MN1 and MN2 having coupled sources connected to a DC supply current terminal 230, and gates respectively connected to differential input terminals 210. Circuits that are cascoded to the differential circuit are respectively connected between respective drains of the nMOS transistor pair MN1 and MN2 and a power supply. Or, drains of the nMOS transistor pair MN1 and MN2 are respectively connected to a differential output terminals (220 in FIG. 1) and also connected to a power supply connection terminal via load resistance elements. A constant current source may be provided between coupled sources of the nMOS transistor pair MN1 and MN2 and the DC supply current terminal 230. Or, a constant current source may be provided between the cross pair 120 and ground. It is to be noted that, in the differential circuit 300, the nMOS transistor pair is not limited to one pair. As shown in FIG. 4B, for example, the differential circuit 300 may have a configuration where the coupled sources are connected to the DC supply current terminal 230, and nMOS transistor pairs (differential pairs) in which gates are respectively connected to the differential input terminals 210, are connected in parallel in a plurality of sets. In FIG. 4B, circuits that are cascoded to the differential circuit respectively may be connected between the power supply and respective drains of nMOS transistor pairs MN1, MN2, . . . MN2n+1, MN2n+2. Or, as a variation of FIG. 4B that includes the plurality of sets of nMOS transistor pairs, as shown in FIG. 4C for example, part of the plurality of sets of nMOS transistor pairs, in which coupled sources are connected in common to the DC supply current terminal 230, receive a signal from differential input terminals which are different from the differential input terminal 210.

FIG. 2 is a diagram showing a configuration of another exemplary embodiment of the present invention. FIG. 2 shows a general configuration of a frequency divider 200 and a voltage controlled oscillator (VCO) 100 which share a direct current from the power supply (a combined circuit in which an oscillator and a frequency divider are combined).

Referring to FIG. 2, a VCO circuit 100 includes a resonance circuit 110 in which an inductor L and capacitors C are connected in parallel, and a VCO cross pair 120 which is connected between outputs of the resonance circuit 110 and ground, which has output ends (differential output terminals) for differentially outputting an oscillation signal. The differential output terminals of the resonance circuit 110 are connected to the input ends (differential input terminal) 210 of the frequency divider 200. As shown in FIG. 3A or 3B, the VCO cross pair 120 includes an nMOS transistor pair M11 and M12 which have sources connected in common to ground, and gates cross connected to respective drains of the transistors M12 and M11. The drains of the nMOS transistors M11 and M12 are respectively connected to the both ends of the inductor (L) 111.

The frequency divider 200 has a power supply connection terminal 270, differential output terminals (frequency divided signal output terminal) 220 for differentially outputting a frequency divided signal, and a DC supply current terminal 230. The power supply connection terminal 270 is connected to a power supply, and the DC supply current terminal 230 is connected to a center tap of the inductor 111 of the resonance circuit of the VCO 100. The DC supply current is supplied to the nMOS transistors M11 and M12 of the VCO cross pair 120 via the inductor 111. The differential outputs of the VCO 100 is AC coupled via capacitors 240a and 240b (coupling capacitors) for DC cutoff to the differential input terminals 210 of the frequency divider 200. The frequency divider 200 differentially outputs a frequency divided signal from the differential output terminals (frequency divided output terminals) 220.

It is to be noted that in FIG. 2, the frequency divider 200 may be an integer frequency divider that includes a source coupled D flip-flops, or may be a part of an integer frequency divider or a fractional frequency divider, each including a differential pair that is able to supply a DC supply current of the frequency divider 200. A description is given below according to a configuration of more specific examples.

### Example 1

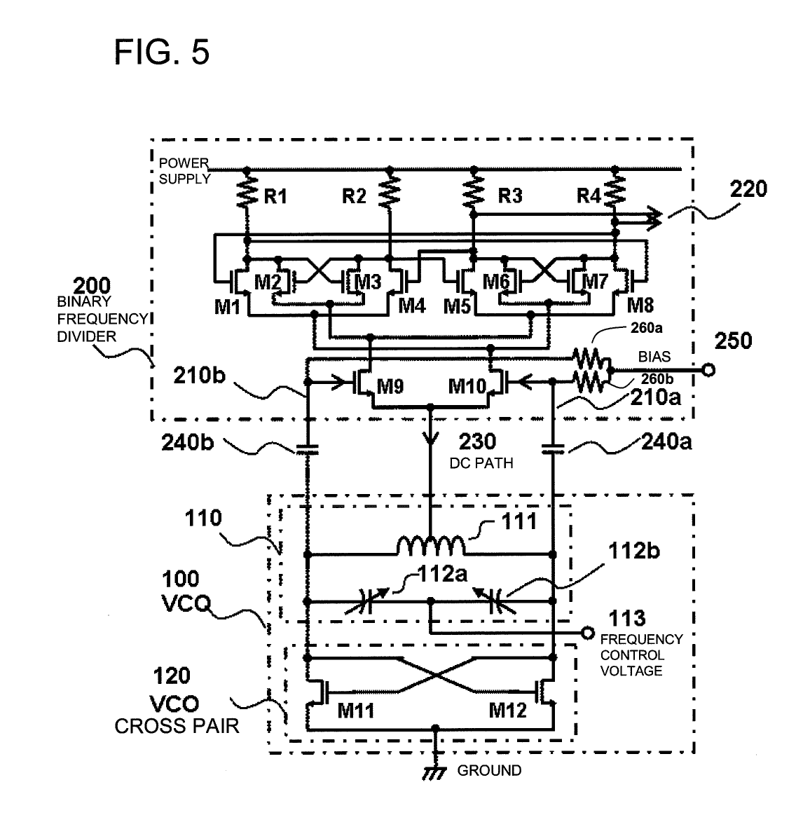

FIG. 5 is a diagram showing a configuration of a first example of the present invention. In FIG. 5, with regard to a frequency divider 200 of FIG. 2, a configuration is shown in which a binary frequency divider 200 (output is toggled each time an oscillation output of a VCO 100 is inputted, and binary frequency division is performed on a VCO oscillation frequency) that is configured by a source coupled T flip-flops (toggle flip-flop), for example, and the VCO 100 share a power supply current.

The binary frequency divider 200 includes:

nMOS transistors M9 and M10 having coupled sources connected to a midpoint (center tap) of an inductor 111, and gates connected respectively to differential signal input ends 210a and 210b,

nMOS transistors M2 and M3 having coupled sources connected to a drain of the transistor M9, and each gate cross-connected to a drain of the other transistor,

nMOS transistors M1 and M4 having coupled sources connected to a drain of the transistor M10,

nMOS transistors M6 and M7 having coupled sources connected to a drain of the transistor M10, and each gate cross-connected to a drain of the other transistor, and

nMOS transistors M5 and M8 having coupled sources connected to the drain of the transistor M9.

The drains of the nMOS transistors M1 and M2, and the gates of the nMOS transistors M3 and M8 are connected to a first end of a load resistance element R1. A second end of the load resistance element R1 is connected to a power supply.

The drains of the nMOS transistors M3 and M4, and the gates of the nMOS transistors M2 and M5 are connected to a first end of a load resistance element R2. A second end of the load resistance element R2 is connected to the power supply.

The drains of the nMOS transistors M5 and M6, and the gates of the nMOS transistors M7 and M4 are connected to a first end of a load resistance element R3. A second end of the load resistance element R3 is connected to the power supply.

The drains of the nMOS transistors M7 and M8, and the gates of the nMOS transistors M6 and M1 are connected to a first end of a load resistance element R4. A second end of the load resistance element R4 is connected to the power supply. An output signal 220 is taken from a first end of the load resistance elements R3 and R4.

In the binary frequency divider 200 configured by the source coupled T flip-flops, differential signal input ends 210a and 210b are connected via capacitors 240a and 240b to terminals of the both ends of the inductor (L) 111 of a resonance circuit of the VCO 100.

Sources of the input transistors M9 and M10 of the binary frequency divider 200 are coupled and connected to a DC supply current terminal 230, to form a DC path (DC power supply current path), and are connected to a center tap of the inductor 111 of the resonance circuit 110.

A description is given below concerning circuit operation in FIG. 5. A DC supply current flows to the drains of the nMOS transistors M1 to M8 via the load resistance elements R1 to R4 of the binary frequency divider 200, flows out from the sources of the nMOS transistors M1 to M8, and flows into the drains of the nMOS transistors M9 and M10. The DC supply current that flows out from the sources of the nMOS transistors M9 and M10 passes through the DC supply current terminal (DS path) 230, flows into the center tap of the inductor 111, is split into two, flows into the drains of the nMOS transistors M11 and M12 of the VCO cross pair 120, flows out from the sources of the nMOS transistors M11 and M12, and flows to ground.

The VCO cross pair 120 that receives a DC supply current forms a negative resistance, forms an energy supply source of the resonance circuit 110 configured from the inductor 111 and varactors (varactor diode: variable capacitance element) 112a and 112b, and causes the VCO 100 to oscillate.

When the VCO 100 oscillates, an AC differential oscillator signal appears at the two ends (differential output terminals) of the VCO 100) of the inductor 111, and passes through the capacitors 240a and 240b to be applied to the gates of the nMOS transistors M9 and M10 of the binary frequency divider 200. The binary frequency divider 200 that receives this signal operates as a T flip-flop (reverses an output state each time an active state input signal is received), and a differential signal after frequency division of ½ of an oscillator signal frequency of the VCO 100 is outputted.

During the abovementioned operation, the value of the DC supply current is related to a voltage applied to a bias terminal 250. That is, the DC supply current of the VCO 100, determined by a bias voltage applied to the bias terminal 250, is entirely shared with the binary frequency divider 200.

As a result, regarding a function of the VCO 100 and the binary frequency divider 200, the DC supply current (power supply current) of the binary frequency divider 200 unit is 0, so that it is possible to realize lower power consumption.

Since the binary frequency divider 200 is configured as a source coupled type, according to a principle of differential operation, at a coupled source node, that is, the DC supply current terminal (DC path) 230, an AC current does not appear, and it is possible to supply the VCO 100 with a pure DC current.

In this way, the operation of the binary frequency divider 200 does not affect operation of the VCO 100. In addition, in a configuration of the related technology of a mixer and a VCO in FIG. 11, the mixer was affected by a disturbing wave from outside, but in the present exemplary embodiment, since a disturbing wave from outside is not present in the binary frequency divider 200, pulling and pushing phenomena in the VCO 100 are not present, as in the abovementioned related technology, and there is no problem in operation stability of the VCO 100.

In a configuration of Example 1 shown in FIG. 5, as described above, the DC supply current of the VCO 100 and the frequency divider 200 is determined by an applied voltage value of a bias terminal 250.

In an actual circuit, even if there is a temperature variation or a power supply voltage variation, since a normal operation of a circuit characteristic, especially, the frequency divider 200, is required, it is necessary to have variation of the DC supply current as small as possible. There is some difficulty in appropriately generating the bias voltage of the bias terminal 250.

When an oscillation amplitude of the VCO 100 changes, the DC current flowing in the VCO cross pair 120 varies, and the supply current of the frequency divider 200 also varies. Thus, there is a possibility that a frequency range in which an operation can be assured will become narrow.

As a means for avoiding this problem, consideration may be given to arranging a constant current source at a source coupled end of the VCO cross pair 120.

However, if this is done, the number of transistor stages that are cascode-connected increases. As a result, in order to have a normal operation of transistors at each stage, it is necessary to increase a power supply voltage. This is in violation of the object of lowering power consumption. In a second example described below, an improvement is made with regard to this point.

### Example 2

FIG. 6 is a diagram showing a configuration of Example 2 of the present invention. In FIG. 6, a configuration is shown in which, with regard to the configuration of FIG. 5, an operation is possible with a constant current source, without increasing power supply voltage. As shown in FIG. 6, in Example 2, nMOS transistors of a VCO cross pair 120 are capacitor coupled. There are provided: nMOS transistors M14 to M16 that are cascode-connected between ground (GND) and a second end of a reference current source 310 having a first end connected to a power supply, and an nMOS transistor M13 having a source connected to ground (GND), a gate connected to a gate of the transistor M14, and a drain connected to coupled sources of nMOS transistors M11 and M12 of the VCO cross pair 120, wherein the gate of the nMOS transistor M14 is connected to a drain of the nMOS transistor M16. The nMOS transistors M13 to M16 form a current mirror circuit, and function as a constant current source for a VCO 100 and a frequency divider 220.

An operation point of the nMOS transistors M10 and M9 connected to differential input terminals 210a and 210b of the binary frequency divider 110 is determined by an applied voltage (a gate voltage of the nMOS transistor M16) of a bias 1. An operation point of the transistors M11 and M12 of the VCO cross pair 120 is determined by an applied voltage (a gate voltage of the nMOS transistor M15) of a bias 2.

As a result thereof, even if an amplitude of an oscillation output signal of the VCO 100 changes, for example, its DC level is decided by the bias 2. Therefore, a DC voltage variation does not occur in source coupled ends of the nMOS transistors M11 and M12 of the VCO cross pair 120. Accordingly, a drain voltage of the nMOS transistor M13 that forms an output (constant current source) of a current mirror is constant, and variation of a current (drain-to-source current) is suppressed.

According to Example 2, without increasing a power supply voltage, it is possible to realize stability of the DC supply current with regard to the VCO 100 and the frequency divider 200 that share a current. As a result, an operation range of the frequency divider 200 can be easily assured, and this is particularly effective with respect to lowering power consumption.

### Example 3

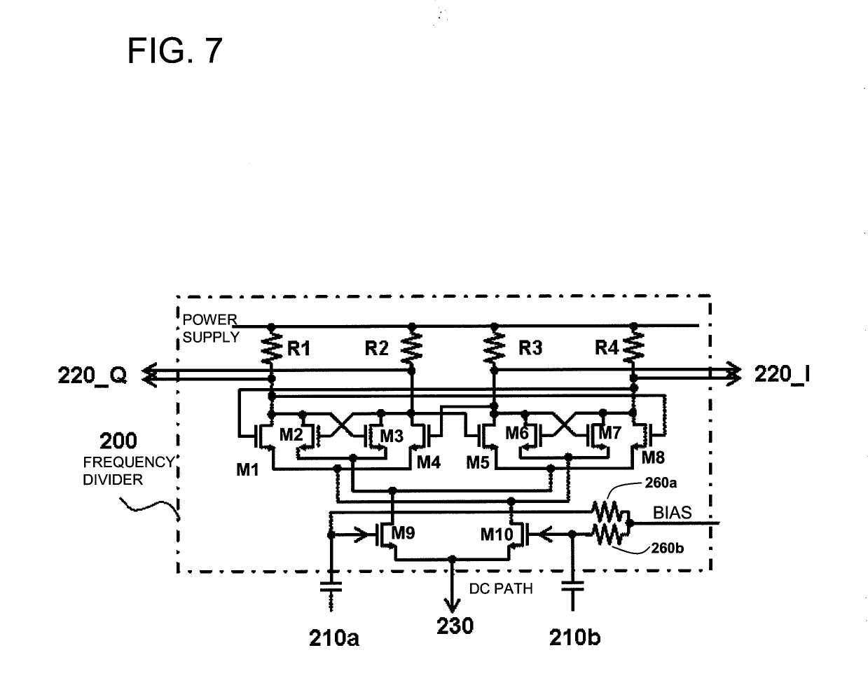

FIG. 7 is a diagram showing a configuration of Example 3 of the present invention. In Example 3, by a binary frequency divider 110 shown in FIG. 5 and FIG. 6 having an output configuration as shown in FIG. 7, it is possible to obtain a quadrature output signal.

Referring to FIG. 7, in-phase differential signals (relative phases are 0 degrees and 180 degrees) are extracted from output ends 220_I of load resistance elements R3 and R4 of a frequency divider 200, and quadrature phase differential signals (relative phases are 90 degrees and 270 degrees) are extracted from output ends 220_Q of resistors R1 and R2. Usage is possible with regard to a quadrature carrier signal of a quadrature modulator or a quadrature demodulator, often used in mobile communication devices. A further effect of low power consumption can be obtained by this configuration.

### Example 4

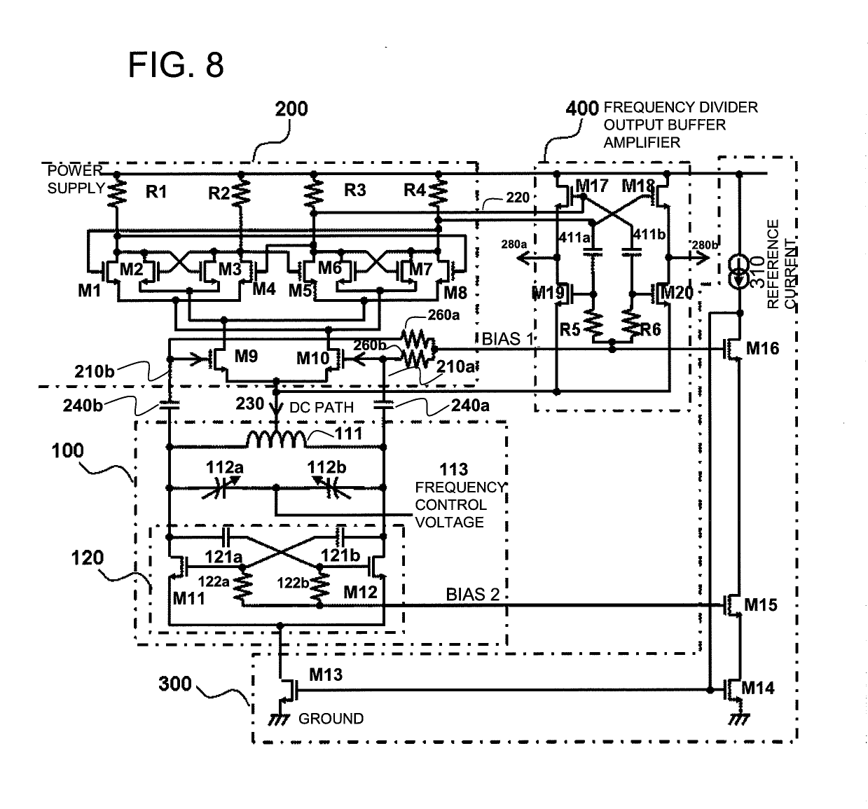

FIG. 8 is a diagram showing a configuration of Example 4 of the present invention. Referring to FIG. 8, there is further provided a buffer amplifier 400 connected to an output side of a binary frequency divider 200 with regard to a configuration shown in FIG. 6. Example will be described with regards to the difference from the configuration of Example 2 shown in FIG. 6.

In FIG. 8, a DC supply current of the buffer amplifier 400 flows together with a DC supply current of the binary frequency divider 200 to a center tap of an inductor 111 of a VCO 100. That is, the DC supply current of the VCO 100 is commonly used by the binary frequency divider 200 and the buffer amplifier 400.

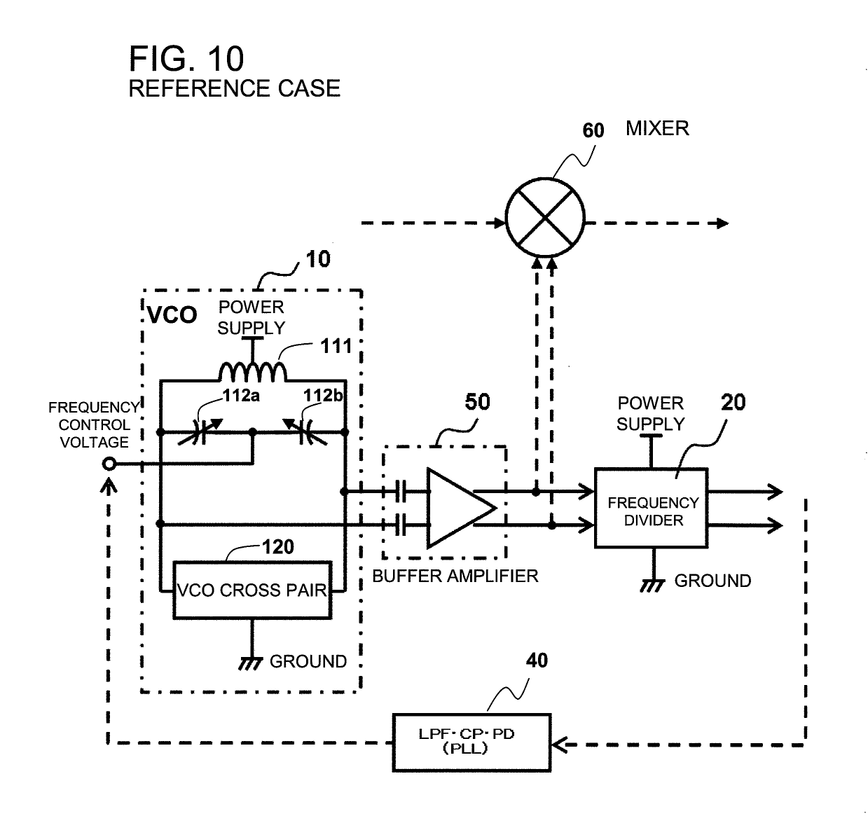

An output signal of a binary frequency divider 110 may be passed to a frequency divider 20 outside of a PLL (refer to FIG. 10) by a configuration of an application circuit, or may be passed to a mixer (60 in FIG. 10). In any case, since a load is attached, a drive power may be necessary. Therefore, according to needs, the buffer amplifier (frequency divider output buffer amplifier) 400 may be arranged at an output of the binary frequency divider 110. With regard to the buffer amplifier 400 shown in FIG. 8, there is an operational effect further stabilizing operation of the binary frequency divider 200.

An operation of the buffer amplifier 400 will now be described. An output signal of the binary frequency divider 200 is differentially applied to gates of nMOS transistors M17 and M18 each operating as a source follower, and after crossing with capacitor coupling by capacitors 411b and 411a, also applied to gates of nMOS transistors M19 and M20 that operate as a source coupled differential circuit. A connection node of sources of the nMOS transistors M19 and M20 of the buffer amplifier 400, and a connection node of sources of nMOS transistors M9 and M10 of the binary frequency divider 200 are connected in common to a DC supply current terminal (DC path) 230, and are connected to a center tap of the inductor 111. A connection node of a source of the nMOS transistor M17 and a drain of the nMOS transistor M19 is an output terminal (node) 280a, and a connection node of a source of the nMOS transistor M18 and a drain of the nMOS transistor M20 is an output terminal (node) 280b.

The nMOS transistor M17 and nMOS transistor M19, each of which is configured as a source follower, operate as push-pull transistors, and the nMOS transistor M18 and nMOS transistor M20, each of which is configured as a source follower, operate as push-pull transistors.

When a rising pulse is supplied to a gate of the nMOS transistor M18, as an output 220 of the binary frequency divider 200, a falling pulse is supplied to a gate of the nMOS transistor M17, a drain-to-source current (source current) flowing from the nMOS transistor M18 to the output terminal 280b increases, and a drain-to-source current flowing from the nMOS transistor M17 to the output terminal 280a decreases. At this time, a drain-to-source current (sink current) of the nMOS transistor M20 that receives an output (a differential pulse of a negative polarity) of the capacitor 411b at its gate, decreases and a charging operation of the output terminal 280b is strengthened by the drain-to-source current of the nMOS transistor M18. On the other hand, a drain-to-source current of the nMOS transistor M19 that receives an output (a differential pulse) of the capacitor 411a at its gate, increases, and a discharging operation of the output terminal 280a is strengthened by the drain-to-source current of the nMOS transistor M19.

In the same way, when a rising pulse is supplied to a gate of the nMOS transistor M17, a falling pulse is supplied to a gate of the nMOS transistor M18, a drain-to-source current of the nMOS transistor M17 increases, a drain-to-source current of the nMOS transistor M18 decreases, a drain-to-source current of the nMOS transistor M19 that receives an output (a differential pulse of a negative polarity) of the capacitor 411a at is gate, decreases, and a drain-to-source current of the nMOS transistor M20 that receives output (a differential pulse of a positive polarity) of the capacitor 411b at is gate, increases. As a result, a discharging operation of the output terminal 280b is strengthened by the drain-to-source current of the nMOS transistor M20 a charging operation of the output terminal 280a is strengthened by the drain-to-source current of the nMOS transistor M17.

With regard to the binary frequency divider 200, even if an oscillation output signal (sinusoidal signal) from the VCO 100 is received, a differential output signal has a pulse waveform (transformed pulse wave) by a latch operation (an operation by a differential latch circuit) of the binary frequency divider 200. That is, other than a fundamental wave (frequency of ½ of an oscillation frequency of the VCO 100), a harmonic component such as a second harmonic, a third harmonic, and so forth, are included in the binary frequency divider 200 output (an output signal of the differential output terminal 220). After capacitance coupling by the capacitors 411a and 411b, this signal is applied to respective gates of the nMOS transistors M19 and M20. The fundamental wave and odd numbered harmonic wave signals do not affect DC bias, since a plus side and a minus side are in symmetry with a DC bias as a center. Even numbered harmonic wave signals such as a second harmonic wave and the like, affect the DC bias.

If the output oscillation (oscillation of an output signal of the differential output terminal 220) of the binary frequency divider 200 becomes large, a DC level becomes larger than a gate bias voltage of the nMOS transistors M19 and M20, by the presence of the even numbered harmonic signals. As a result, the DC supply current of the buffer amplifier 400 increases.

However, a total current of the binary frequency divider 200 and the buffer amplifier 400 is equivalent to a current of the DC supply current terminal 230, that is, the DC supply current of the VCO 100, and is set to a constant current value (steady value) of a constant current source M13. As a result, when the DC supply current of the buffer amplifier 400 increases, the DC supply current (current sum of current flowing in the nMOS transistors M9 and M10) of the binary frequency divider 200 decreases. As a result, an output amplitude of the binary frequency divider 200 (amplitude of the output signal of the differential output terminal 220) decreases. That is, according to the present exemplary embodiment, by providing the buffer amplifier 400, the output amplitude of the binary frequency divider 200 is more stably held, to provide an effect of improving operation stability.

In this regard, in a case of a configuration where the binary frequency divider 200 shown in FIG. 8 is modified to that shown in FIG. 7, and the buffer amplifiers are connected to an in-phase output and a quadrature-phase output, this is particularly suited for driving a quadrature modulator or a quadrature demodulator (in general these have a heavy load).

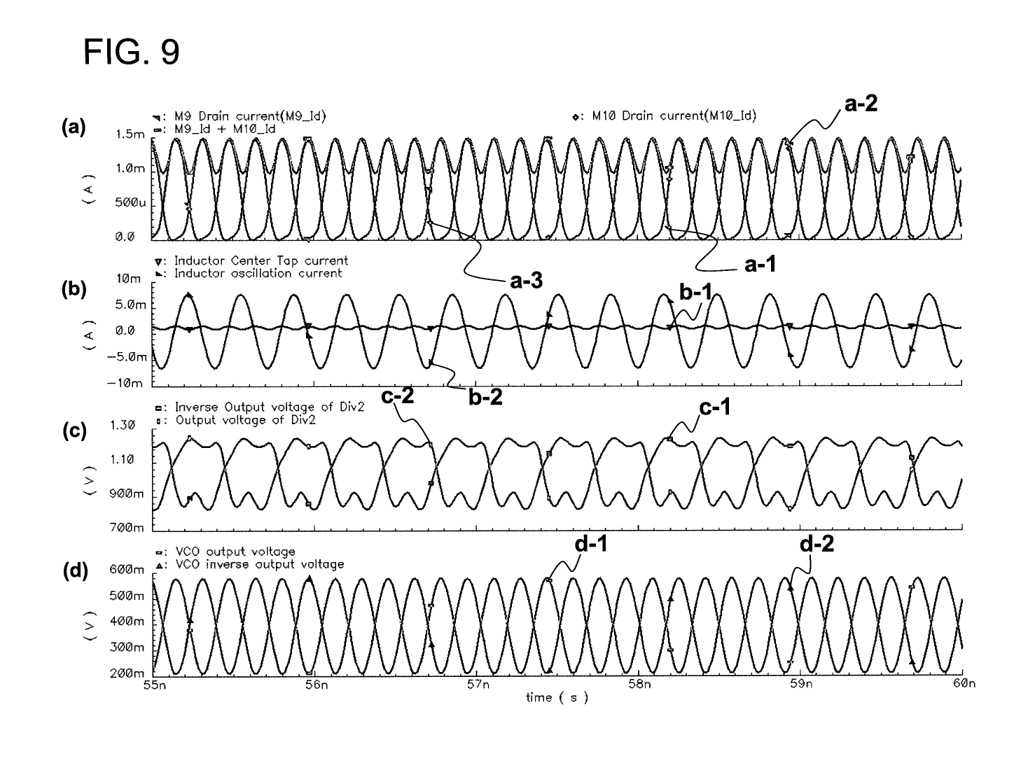

FIG. 9 shows a simulation result of a circuit operation of the present exemplary embodiment shown in FIG. 5. In (a) of FIG. 9, a waveform a-1 is a drain current M9_Id of the transistor M9 of FIG. 5, a-2 is a drain current M10_Id of the transistor M10, and a-3 is a current waveform of the drain current M9_Id of the transistor M9+the drain current M10_Id of the transistor M10. In (b) of FIG. 9, b-1 is a current waveform of a center tap of an inductor 111 of FIG. 5, and b-2 is an oscillation (resonance) current waveform of the inductor 111. In (c) of FIG. 9, c-1 is an inverse output (voltage waveform) of the binary frequency divider 200, and c-2 is a non-inverse output (voltage waveform) of the binary frequency divider 200. In (d) of FIG. 9, d-1 is an output voltage waveform of the differential output terminal 220 of the VCO 100, and d-2 is an inverse output voltage waveform of the VCO 100. It is shown that the output of the binary frequency divider 200 in (c) of FIG. 9 performs binary frequency division of output of the VCO 100 in (d) of FIG. 9, and that an approximately constant DC current is supplied to the center tap of the inductor 111 of a resonance circuit 110 from a DC path 230 that is a source coupled node of the transistors M9 and M10.

As described above, according to the present invention, in a high frequency circuit, the voltage control oscillator (VCO) having a relatively large current consumption and the frequency divider are made to share a DC supply current, without an increase of a power supply voltage, and a significant effect is achieved in lowering power consumption.

While sharing the power supply current, the VCO and the frequency divider can both operate stably.

It is to be noted that, in the abovementioned exemplary embodiment, a description was given according to an example of a configuration where the transistors forming the VCO cross pair 120, the transistors forming the frequency divider 200, and the transistors forming the bias and the constant current circuit 300 are nMOS transistors, but changing polarity, a configuration is also possible with PMOS transistors. Furthermore, the configuration of the voltage control oscillator is clearly not limited to the above-mentioned configuration or the like. Furthermore, in the above-mentioned exemplary embodiments, a description was given of MOS transistors as an example, but a configuration with bipolar transistors (bipolar junction transistors) is also possible. In this case, M1 to M12 of FIG. 5 are configured by npn-type bipolar transistors, and coupled emitters of the bipolar transistors are connected to the DC supply current terminal 230. In the same way, the transistors M13 to M16 of FIG. 6 are configured by npn-type bipolar transistors. In addition, the transistors M17 to M20 of the buffer amplifier 400 are also configured by npn-type bipolar transistors, and the transistors M17 and M18 operate as emitter followers.

Below, a description is given of correspondences between invention claims and embodiments. It is to be noted that reference symbols inside parentheses are for describing a configuration of the present invention, and clearly are not to be interpreted as limiting the present invention.

A device according to the present invention includes:

an oscillator including a resonance circuit (110, 110A) of a parallel in which an inductor (L) and a capacitor (C) are connected in parallel, and another circuit (200, 300) including a differential pair (M9 and M10) that receives an oscillation output signal of the oscillator and that forms first and second current paths from a first power supply side, wherein ends of the first and second current paths on a side opposite to the first power supply are coupled together and connected to a midpoint (center tap) of the inductor (L) of the oscillator and the oscillator and the another circuit are cascode-connected between a second power supply (GND) and the first power supply.

The device according to the present invention may include a frequency divider including the differential pair (M9 and M10).

A first transistor pair (M9 and M10) forming the differential pair receives, as differential inputs, outputs of the both ends of the resonance circuit at control terminals (gate terminals), second terminals (source terminals) of the first transistor pair are connected in common and are connected to the center tap of the inductor (111) of the oscillator and form a first end (230) on a side opposite to the first power supply of the current path, and first terminals (drain terminals) of the first transistor pair (M9 and M10) are connected to a path to the first power supply side.

The oscillator (100) may include first and second transistors (M11 and M12), with first terminals each connected to the both ends of the resonance circuit (110), and second terminals connected in common to the second power supply, wherein control terminals (gate terminals) of the first and second transistors are respectively cross-connected to first terminals (drain terminals) of the second and first transistors.

The oscillator (100) may include first and second variable capacitance elements (112a and 112b) in which the capacitors of the resonance circuit (110) are connected in series between the both ends of the inductor (111), and a control voltage (113) is applied to a connection node of the first and second variable capacitance elements. The control elements (gate terminals) of the first transistor pair (M9 and M10) of the differential stage are respectively AC coupled to outputs of both ends of the resonance circuit (110), and also are connected to a first bias voltage supply terminal (250 in FIG. 5) via first and second resistors (260a and 260b in FIG. 5) respectively.

In the oscillator (100), control terminals (gate terminals) of the first and second transistors (M11 and M12) may be respectively cross-connected to first terminals (drain terminals) of the second and first transistors (M12 and M11) via fifth and sixth capacitors (121b and 121a of FIG. 5), and the control terminals (gate terminals) of the first and second transistors (M11 and M12) are respectively connected to a second bias voltage supply terminal (bias 2) via third and fourth resistors (122a and 122b in FIG. 6). First and second input terminals of the frequency divider (200) are respectively connected to the first bias voltage supply terminal (bias 1) via the first and second resistors (260a and 260b in FIG. 6). The present invention is further provided with a bias and constant current circuit (300 in FIG. 6).

In the present invention, a bias and constant current circuit (300 in FIG. 6) may include:

a third transistor (M13) that is connected between a second power supply (GND) and commonly connected second terminals (source terminals) of the first and second transistors (M11 and M12) of the oscillator (100);

a reference current source (310) having a first end connected to the first power supply; and

fourth to sixth transistors (M14 to M16) that are cascode connected between a second end of the reference current source (310) and the second power supply (GND), wherein the control terminal (gate terminal) of the fourth transistor (M14) is connected to the control terminal (gate terminal) of the third transistor (M13) and also is connected to a connection point of a second end of the reference current source (310) and the sixth transistor (M16). The control terminal (gate terminal) of the sixth transistor (M16) and the control terminal (gate terminal) of the fifth transistor (M15) are the first bias voltage supply terminal (bias 1) and the second bias voltage supply terminal (bias 2), respectively.

In the present invention, the frequency divider (200) may include a flip-flop including a transistor pair in which second terminals (sources) are coupled with the first terminals (drain terminals) of the first transistor pair (M9 and M10) of the differential stage, respectively.

In the present invention, the frequency divider (200) may include:

ninth and tenth transistors (M9 and M10 in FIG. 5) having control terminals (gate terminals) connected to the first and second input ends (210b and 210a), second terminals coupled and connected to the resonance circuit of the oscillator, as a second power supply terminal of the frequency divider;

eleventh and fourteenth transistors (M1 and M4 in FIG. 5) having second terminals (source terminals) connected in common to a first terminal (drain terminal) of the tenth transistor (M10);

twelfth and thirteenth transistors (M2 and M3 in FIG. 5) having second terminals (source terminals) connected in common to a first terminal (drain terminal) of the ninth transistor (M9);

fifteenth and eighteenth transistors (M5 and M8 in FIG. 5) having second terminals (source terminals) connected in common to the first terminal (drain terminal) of the ninth transistor (M9); and

sixteenth and seventeenth transistors (M6 and M7 in FIG. 5) having second terminals (source terminals) connected in common to the first terminal (drain terminal) of the tenth transistor (M10).

In the present invention, there may be provided a configuration in which the first terminals (drain terminals) of the eleventh and twelfth transistors (M11 and M12) and the control terminals (gate terminals) of the thirteenth and eighteenth transistors (M3 and M8) are connected in common and are connected to a first end of a first load element (R1 in FIG. 5). In the present invention, the first terminals (drain terminals) of the thirteenth and fourteenth transistors (M3 and M4) and the control terminals (gate terminals) of the twelfth and fifteenth transistors (M2 and M5) are connected in common and are connected to a first end of a second load element (R2 in FIG. 5). In the present invention, the first terminals (drain terminals) of the fifteenth and sixteenth transistors (M5 and M6) and the control terminals (gate terminals) of the fourteenth and seventeenth transistors (M4 and M7) are connected in common and are connected to a first end of a third load element (R3 in FIG. 5). In the present invention, the first terminals (drain terminals) of the seventeenth and eighteenth transistors (M7 and M8) and the control terminals (gate terminals) of the eleventh and sixteenth transistors (M1 and M6) are connected in common and are connected to a first end of a fourth load element (R4 in FIG. 5).

In the present invention, there may be provided a configuration in which second ends of the first to the fourth load elements (R1, R2, R3, and R4) are connected in common and are connected to the first power supply as a first power supply terminal of the frequency divider (200). The first ends of the third and fourth load elements (R3 and R4) are connected to a differential output pair (220 in FIG. 5).

In the present invention, there may be provided a configuration in which an in-phase signal is differentially outputted from a first end of the third and fourth load elements (R3 and R4), and a quadrature signal is differentially outputted from a first end of the first and second load elements (R1 and R2).

In the present invention, there may be provided a buffer amplifier (400 in FIG. 6), which receives an output of the frequency divider (200) between the first power supply and the second power supply terminal (230) of the frequency divider (200). The buffer amplifier (400) may include:

seventh and eighth transistors (M17 and M18 in FIG. 8) that are connected to the first power supply, respectively receive differential outputs of the frequency divider (200), and form a source follower; and

nineteenth and twentieth transistors (M19 and M20 in FIG. 8) that are connected between output of the seventh and eighth transistors (M17 and M18) and the second power supply terminal of the frequency divider, wherein control terminals (gate terminals) of the nineteenth and twentieth transistors (M19 and M20) are respectively connected to control terminals (gate terminals) of the eighth and seventh transistors (M8 and M7) via the fifth and sixth capacitors (411a and 411b of FIG. 8), and are also connected to the first bias voltage supply terminal (bias 1) via the third and fourth resistors (R5 and R6 in FIG. 8).

It is to be noted that each disclosure of the above-mentioned patent document is incorporated herein by reference. Modifications and adjustments of embodiments and examples are possible within the bounds of the entire disclosure (including the scope of the claims) of the present invention, and also based on fundamental technological concepts thereof. Furthermore, a wide variety of combinations and selections of various disclosed elements are possible within the scope of the claims of the present invention. That is, the present invention clearly includes every type of transformation and modification that a person skilled in the art can realize according to the entire disclosure including the scope of the claims and to technological concepts thereof.

What is claimed is:

1. An oscillator combined circuit comprising:
an oscillator including a resonance circuit that includes an inductor and a capacitors connected in parallel; and
a circuit including a differential pair that receives an oscillation output signal of said oscillator, and that forms first and second current paths from a first power supply, said first and second current paths having respective first ends on a side opposite to said first power supply coupled together and connected to a midpoint of said inductor of said oscillator,
said oscillator and said circuit including said differential pair being cascode-connected between a second power supply and said first power supply.

2. The oscillator combined circuit according to claim 1, comprising a frequency divider including said circuit including said differential pair.

3. The oscillator combined circuit according to claim 2, wherein said differential pair comprises:
a first transistor pair having control terminals that differentially receive outputs at both ends of said resonance circuit,
said first transistor pair having second terminals that form respectively first ends of said first and second current paths on a side opposite to said first power supply, said first ends of said first and second current paths being coupled together and connected to a midpoint of said inductor of said oscillator,
said first transistor pair having first terminals that form second ends of said first and second current paths on a side of said first power supply.

4. The oscillator combined circuit according to claim 3, wherein said oscillator further comprises
first and second transistors having first terminals respectively connected to both ends of said resonance circuit, and having second transistors having second terminals connected in common to said second power supply, said first and second transistors having control terminals cross-connected to said first terminals of said second and first transistors, respectively.

5. The oscillator combined circuit according to claim 4, wherein said control terminals of said first and second transistors are cross-connected via capacitors to first terminals of said second and first transistors, respectively, and receive a bias voltage.

6. The oscillator combined circuit according to claim 4, wherein said capacitor of said resonance circuit in said oscillator comprises
first and second variable capacitance elements connected in series in parallel with said inductor, a control voltage being applied to a connection point of said first and second variable capacitance elements.

7. The oscillator combined circuit according to claim 3, wherein said control terminals of said first transistor pair are respectively AC-coupled to outputs of both ends of said resonance circuit, and are respectively connected via first and second resistors to a first bias voltage supply terminal.

8. The oscillator combined circuit according to claim 4, wherein said control terminals of said first transistor pair are connected respectively via first and second resistors to a first bias voltage supply terminal,
wherein in said oscillator, said control terminals of said first and second transistors are cross-connected via fifth and sixth capacitors to said first terminals of said second and first transistors, respectively, and
said control terminals of said first and second transistors are connected respectively via third and fourth resistors to a second bias voltage supply terminal, and wherein
said oscillator combined circuit further comprises
a bias and constant current circuit that includes:
a third transistor connected between said commonly connected second terminals of said first and second transistors of said oscillator and said second power supply;
a reference current source having a first end connected to said first power supply; and
fourth to sixth transistors cascode connected between a second end of said reference current source and said second power supply,
a control terminal of said fourth transistor being connected to a control terminal of said third transistor and also connected to a connection node of a second end of said reference current source and said sixth transistor,
a control terminal of said sixth transistor and a control terminal of said fifth transistor being connected to said first bias voltage supply terminal and said second bias voltage supply terminal respectively.

9. The oscillator combined circuit according to claim 2, wherein said frequency divider comprises
at least one flip-flop that includes a transistor pair having second terminals coupled to associated one of said first terminals of said first transistor pair.

10. The oscillator combined circuit according to claim 2, wherein said frequency divider includes:
ninth and tenth transistors forming said first transistor pair having control terminals connected to first and second input ends of said frequency divider, second terminals coupled together and connected to a midpoint of an inductor of said resonance circuit of said oscillator,
eleventh and fourteenth transistors having second terminals connected in common to a first terminal of said tenth transistor,
twelfth and thirteenth transistors having second terminals connected in common to a first terminal of said ninth transistor,
fifteenth and eighteenth transistors having second terminals connected in common to the first terminal of said ninth transistor, and
sixteenth and seventeenth transistors having second terminals connected in common to the first terminal of said tenth transistor, wherein
first terminals of said eleventh and twelfth transistors and control terminals of said thirteenth and eighteenth transistors are connected in common to a first end of a first load element,
first terminals of said thirteenth and fourteenth transistors and control terminals of said twelfth and fifteenth transistors are connected in common to a first end of a second load element,
first terminals of said fifteenth and sixteenth transistors and control terminals of said fourteenth and seventeenth transistors are connected in common to a first end of a third load element,
first terminals of said seventeenth and eighteenth transistors and control terminals of said eleventh and sixteenth transistors are connected in common to a first end of a fourth load element,
second ends of said first to fourth load elements are connected in common to a first power supply terminal of said frequency divider which is connected to said first power supply, and
first ends of said third and fourth load elements are connected to differential output terminals, respectively.

11. The oscillator combined circuit according to claim 10, wherein, as output of said frequency divider, an in-phase signal is differentially output from first ends of said third and fourth load elements, and a quadrature signal is differentially output from first ends of said first and second load elements.

12. The oscillator combined circuit according to claim 2, further comprising
a buffer circuit receiving an output of said frequency divider and arranged between said first power supply and said commonly connected first ends of said differential pair on a side opposite to said first power supply.

13. The oscillator combined circuit according to claim 10, comprising:
seventh and eighth transistors connected to said first power supply, seventh and eighth transistors having control terminal for respectively receiving differential outputs of said frequency divider, seventh and eighth transistors each outputting a voltage following a voltage received, and
nineteenth and twentieth transistors connected between a connection node of a midpoint of said inductor of said resonance circuit and a connection node of second terminals of said first transistor pair, and outputs of said seventh and eighth transistors,
control terminals of said nineteenth and twentieth transistors being respectively connected to control terminals of said eighth and seventh transistors via fifth and sixth capacitors, and also connected to said first bias voltage supply terminal via third and fourth resistors,
a differential signal being output from a connection node of said seventh and nineteenth transistors and a connection node of said eighth and twentieth transistors.

14. A semiconductor device comprising the oscillator combined circuit according to claim 1.

15. A communication device comprising the oscillator combined circuit according to claim 1.

16. A method of reusing a current in a circuit comprising an oscillator having a resonance circuit including an inductor and a capacitor connected in parallel; and a circuit including a differential pair that receives an oscillation output signal of said oscillator and forms first and second current paths from a first power supply side, said method comprising:
connecting respective first ends of said first and second current paths on a side opposite to said first power supply in common to a midpoint of said inductor of said oscillator;
cascode-connecting said oscillator and said circuit between a second power supply and said first power supply; and
using, by said oscillator, a current supplied from said commonly connected first ends of said first and second current paths of said circuit including the differential pair, as a power supply current of said oscillator.
